(19) United States
(12) Patent Application Publication
(10) Pub. No.: US 2024/0213081 A1
(43) Pub. Date: Jun. 27, 2024

(54) SUBSTRATE SUPPORTS WITH MESOCHANNEL ASSEMBLIES

(71) Applicant: LAM RESEARCH CORPORATION, Fremont, CA (US)

(72) Inventors: Spoorthi SUBRAMANYA, Bangalore (IN); Shivakumara REVANNA, Bangalore (IN); Kevin FLYNN, Novato, CA (US); Chandrashekara Kuashik GANDUR BALAGANGADHARA, Bangalore (IN); Muskaan JAIN, Bangalore (IN); Santosh Kumar KRISHNA MURTHY, Bangalore (IN)

(21) Appl. No.: 18/291,444

(22) PCT Filed: Jul. 19, 2022
(86) PCT No.: PCT/US2022/037551

§ 371 Date: Jan. 23, 2024

Related U.S. Application Data
(60) Provisional application No. 63/225,906, filed on Jul. 26, 2021.

(51) Int. Cl. H01L 21/687; C23C 16/458; H01J 37/32

(52) U.S. Cl. CPC H01L 21/68785; C23C 16/4586; H01J 37/32724; H01J 2237/002

(57) ABSTRACT

A substrate support includes a body and a mesochannel assembly. The body is configured to support a substrate within a substrate processing system. The first mesochannel assembly is disposed in the body and includes: a first mesochannels; a first supply manifold supplying coolant to each of the first mesochannels; and a first return manifold receiving the coolant from the first mesochannels. The first mesochannels are disposed between the first supply manifold and the first return manifold to facilitate flow of the coolant from the first supply manifold to the first return manifold.

### CROSS-REFERENCE TO RELATED APPLICATIONS

This application claims the benefit of U.S. Provisional Application No. 63/225,906, filed on Jul. 26, 2021. The entire disclosure of the application referenced above is incorporated herein by reference.

### FIELD

The present disclosure relates to controlling temperature profiles of substrate supports, and more particularly to cooling substrate supports.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate support (e.g., a pedestal or electrostatic chuck) includes a body. Electrostatic clamping and radio frequency (RF) electrodes and a cooling channel can be disposed in the body. The cooling channel includes one or more inlets and one or more outlets. Coolant is supplied from a reservoir to the inlet and returned to the reservoir through the outlet. The cooling channel may be spiral-shaped and extend laterally across the body to cool an area below a substrate supported by the substrate support.

When designed to provide more cooling in a center area of the body, the inlet of the cooling channel is typically disposed near a center of the body and the outlet of the cooling channel is disposed near an outer circumferential edge of the body. When designed to provide more cooling at the outer circumferential edge of the body, the inlet of the cooling channel is disposed near an outer circumferential edge of the body and the outlet is disposed near a center of the body. To provide an averaging effect, where a similar amount of cooling is provided across the body, both the inlet and the outlet of the cooling channel may be disposed near the center of the body. The cooling channel may include (i) a first portion extending from the center of the body in a spiraling manner to an outer circumferential edge of the body, and (ii) a second portion extending from the outer circumferential edge of the body and returning back to the center of the body following the path of the first portion. The second portion extends parallel to and near the first portion and includes fluid flowing is an opposite direction as the first portion, which causes temperatures along the path to be averaged providing more uniform cooling laterally across the substrate support.

### SUMMARY

A substrate support is provided and includes a body and a mesochannel assembly. The body is configured to support a substrate within a substrate processing system. The first mesochannel assembly is disposed in the body and includes: a first mesochannels; a first supply manifold supplying coolant to each of the first mesochannels; and a first return manifold receiving the coolant from the first mesochannels. The first mesochannels are disposed between the first supply manifold and the first return manifold to facilitate flow of the coolant from the first supply manifold to the first return manifold.

In other features, the first mesochannels extend from the supply manifold to the return manifold and direct coolant from the supply manifold to the return manifold.

In other features, a cross-section of each of the first mesochannels has a hydraulic diameter of less than 3.0 mm.

In other features, the supply manifold is disposed radially inward of the return manifold. In other features, the supply manifold is disposed radially outward of the return manifold. In other features, the mesochannels extend parallel to each other and in a spiral pattern. In other features, the mesochannels extend from a center area of the body to an area adjacent an outer circumferential edge of the body and back to the center area of the body.

In other features, the supply manifold is disposed adjacent to the return manifold. In other features, the supply manifold and the return manifold are disposed in a center area of the body. In other features, the supply manifold and the return manifold are disposed along an outer circumferential edge of the body. In other features, the supply manifold and the return manifold extend in a radial direction. In other features, the mesochannels are concentric.

In other features, the mesochannels are annular-shaped. In other features, the mesochannels having different layout patterns with different shaped bends. In other features, at least one of cross-section widths and cross-section heights of the mesochannels are uniform. In other features, the mesochannels include: a first mesochannel having a first cross-section width; and a second mesochannel disposed radially inward of the first mesochannel and having a second cross-section width. The second cross-section width is smaller than the first cross-section width.

In other features, the mesochannels have a same length. In other features, the mesochannels include: a first mesochannel having a first length; and a second mesochannel disposed radially inward of the first mesochannel and having a second length. The second length is different than the first length. In other features, the second length is shorter than the first length.

In other features, the mesochannels include: a first mesochannel; a second mesochannel disposed radially inward of the first mesochannel such that a first gap exists between the first mesochannel and the second mesochannel; and a third mesochannel disposed radially inward of the second mesochannel such that a second gap exists between the second mesochannel and the third mesochannel.

In other features, a size of the first gap is equal to a size of the second gap. In other features, a size of the first gap is different than a size of the second gap. In other features, the body includes: a first plate defining a first portion of the mesochannel assembly; and a second plate attached to the first plate and defining a second portion of the mesochannel assembly.

In other features, the first portion includes grooves. The grooves define three sides of each of the first mesochannels. The second portion includes a fourth side of each of the first mesochannels

In other features, the mesochannel assembly is a first mesochannel assembly. The body includes: a first layer including the first mesochannel assembly; and a second layer including a second mesochannel assembly.

In other features, the second mesochannel assembly includes: second mesochannels; a second supply manifold supplying coolant to each of the second mesochannels; and a second return manifold receiving the coolant from the second mesochannels. The second mesochannels are disposed between the second supply manifold and the second return manifold to facilitate flow of the coolant from the second supply manifold to the second return manifold

In other features, the second mesochannels extend from the second supply manifold to the second return manifold and direct coolant from the second supply manifold to the second return manifold.

In other features, the substrate support further includes: a first crossover channel extending between the supply manifold of the first mesochannel assembly to the second supply manifold of the second mesochannel assembly; and a second crossover channel extending between the return manifold of the first mesochannel assembly to the second return manifold of the second mesochannel assembly. In other features, the first mesochannel assembly is disposed over the second mesochannel assembly.

In other features, the first layer is disposed on the second layer. The supply manifold of the first mesochannel assembly is disposed over the second return manifold of the second mesochannel assembly. The return manifold of the first mesochannel assembly is disposed over the second supply manifold of the second mesochannel assembly. In other features, the mesochannel assembly is a first mesochannel assembly. The body includes mesochannel assemblies including the first mesochannel assembly.

In other features, the mesochannel assemblies are each disposed in at least a portion of a same layer of the body. In other features, the mesochannel assemblies are each disposed in and defined by a same two plates of the body. In other features, the mesochannel assemblies are each disposed in different layers of the body.

In other features, the supply manifold is disposed radially outward of the return manifold. The mesochannels extend radially between the supply manifold and the return manifold. In other features, a width of at least one of the mesochannels varies from the supply manifold to the return manifold.

In other features, the supply manifold is annular-shaped and discontinuous such that a gap exists between ends of the supply manifold. The return manifold is annular-shaped and discontinuous such that a gap exists between ends of the return manifold.

In other features, the supply manifold is disposed radially inward of the return manifold. The mesochannels extend radially between the supply manifold and the return manifold. In other features, a width of at least one of the mesochannels varies from the supply manifold to the return manifold.

In other features, the supply manifold is annular-shaped and discontinuous such that a gap exists between ends of the supply manifold. The return manifold is annular-shaped and discontinuous such that a gap exists between ends of the return manifold.

In other features, the mesochannels include at least one mesochannel disposed at varying vertical levels within the body. In other features, the mesochannels include at least one mesochannel having cross-sections that vary in height along a length of the at least one mesochannel.

In other features, the mesochannels include at least one mesochannel having cross-sections that transition between increasing in height and decreasing in height.

In other features, the body includes a first channel layer including a first plurality of mesochannel assemblies. The first plurality of mesochannel assemblies include the first mesochannel assembly and a second mesochannel assembly arranged radially inward of the first mesochannel assembly.

In other features, the body includes a first channel layer including first mesochannel assemblies. The first mesochannel assemblies includes a first supply manifold, a first return manifold and first mesochannels connecting the first supply manifold to the first return manifold. The first mesochannel layer includes of a second mesochannel assembly arranged radially inward of the first mesochannel assembly.

In other features, the second mesochannel assembly includes a second supply manifold, a second return manifold and second mesochannels connecting the second supply manifold to the second return manifold. In other features, the first mesochannel layer includes a third mesochannel assembly arranged radially inward of the second mesochannel assembly.

In other features, coolant flow through the first mesochannel assembly is in a same direction as coolant flow through the second mesochannel assembly and the third mesochannel assembly.

In other features, the body includes a first cutout layer comprising a first cutout supplying coolant to first manifolds of the first mesochannel assemblies. In other features, the first cutout layer includes a second cutout receiving coolant from second manifolds of the first mesochannel assemblies. In other features, the body includes a second channel layer disposed on the first channel layer and including a second plurality of mesochannel assemblies.

In other features, a pattern of the second plurality of mesochannel assemblies is a same pattern as the first mesochannel assemblies. Coolant flows through the second plurality of mesochannel assemblies in an opposite direction as coolant flow through the first plurality of mesochannel assemblies.

In other features, the body includes: a first cutout layer including a first cutout supplying coolant to or receiving coolant from first manifolds of the first plurality of mesochannel assemblies; and a second cutout layer including a second cutout supplying coolant to or receiving coolant from second manifolds of the second plurality of mesochannel assemblies.

In other features the first mesochannel assembly includes transition channels connecting inner mesochannels to outer mesochannels, each of the transition channels connecting a respective one of the inner mesochannels to a respective one of the outer mesochannels, each of the outer mesochannels being disposed radially outward of at least one of the inner mesochannels.

In other features, the substrate support further includes: a supply channel supplying coolant to the first plurality of mesochannel assemblies; and a return channel receiving coolant from the first plurality of mesochannel assemblies.

In other features, a substrate processing system is provided and includes: the substrate support; a first line supplying the coolant to the supply manifold; a second line supplying the coolant to the return manifold; and a pump connected to at least one of the first line and the second line and circulating the coolant through the mesochannel assembly.

In other features, the substrate processing further includes: a temperature sensor configured to detect a temperature within a processing chamber, where the substrate support is disposed in the processing chamber; and a controller configured to control operation of the pump based on the temperature.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 a functional block diagram of an example substrate processing system including a substrate support having a mesochannel assembly in accordance with an example of the present disclosure;

FIG. 2 is a top cross-sectional view of an example mesochannel assembly in accordance with the present disclosure;

FIG. 3 is a top cross-sectional view of a portion of an example substrate support taken through a manifold layer of the substrate support and including a mesochannel assembly with multiple spiral-shaped mesochannels in accordance with the present disclosure;

FIG. 4A is a top cross-sectional view of a portion of an example substrate support taken through a first mesochannel layer of the substrate support and including concentric mesochannels in accordance with the present disclosure;

FIG. 4B is a top cross-sectional view of an example second mesochannel layer of the substrate support of FIG. 4A including concentric mesochannels in accordance with the present disclosure;

FIG. 4C is an example cross-sectional side view through section line A-A of the substrate support of FIG. 4A in accordance with the present disclosure;

FIG. 5A is a top cross-sectional view of a portion of an example substrate support taken through a first mesochannel layer of the substrate support and including concentric mesochannels with different widths in accordance with the present disclosure;

FIG. 5B is a top cross-sectional view of an example second mesochannel layer of the substrate support of FIG. 5A including concentric mesochannels with different widths in accordance with the present disclosure;

FIG. 5C is an example side cross-sectional view through section line B-B of the substrate support of FIG. 5A in accordance with the present disclosure;

FIG. 6A is a top cross-sectional view of a portion of an example substrate taken through a first mesochannel layer of the substrate support including a mesochannel layer with multiple zones and having a pair of manifolds in accordance with the present disclosure;

FIG. 6B is a top cross-sectional view of another portion of the substrate support of FIG. 6A including another mesochannel layer with multiple zones and having a pair of manifolds in accordance with the present disclosure;

FIG. 7 is a top cross-sectional view of a portion of an example substrate support including a layer with multiple zones with respective dedicated pairs of manifolds in accordance with the present disclosure;

FIG. 8 is a bottom cross-sectional view of a portion of an example substrate support including non-continuous annular-shaped manifolds and uniform width mesochannels that extend radially in accordance with the present disclosure;

FIG. 9 is a bottom cross-sectional view of a portion of an example substrate support including non-continuous annular-shaped manifolds and varying width mesochannels that extend radially in accordance with the present disclosure;

FIG. 10 is a side cross-sectional view of a portion of a substrate support illustrating a mesochannel disposed at varying vertical levels within the substrate support in accordance with the present disclosure; and

FIG. 11 is a side cross-sectional view of a portion of a substrate support illustrating a mesochannel disposed at varying vertical levels within the substrate support and having cross-sections that vary in height in accordance with the present disclosure;

FIG. 12 is a side cross-sectional view of a portion of a substrate support illustrating a mesochannel having cross-sections that transition between increasing in height and decreasing in height in accordance with the present disclosure;

FIG. 13A is a top cross-sectional view of a portion of an example substrate support including a single layer of mesochannels with an alternating mesochannel supply and return channel pattern where adjacent supply and return channels having opposite directions of coolant flow in accordance with the present disclosure;

FIG. 13B is a cross-section view through section line C-C of the substrate support of FIG. 13B in accordance with the present disclosure;

FIG. 14A is a cross-section view of a portion of an example substrate support including lower layers having a first set of spiral-shaped mesochannel assemblies in accordance with the present disclosure;

FIG. 14B is a cross-section view of another portion of the example substrate support of FIG. 14A including upper layers having a second set of spiral-shaped mesochannel assemblies;

FIG. 15A is a cross-section through section line D-D of FIG. 14B for the stacked combination of the portions of FIGS. 14A and 14B; and

FIG. 15B is a cross-section through section line E-E of FIG. 14B for the stacked combination of the portions of FIGS. 14A and 14B.

In the drawings, reference numbers may be reused to identify similar and/or identical elements.

### DETAILED DESCRIPTION

In substrate processing systems, such as dry etch substrate processing systems, temperature profiles of a substrate are controlled in order to achieve a predetermined etch profile during processing of the substrate. The etch profile of the substrate is sensitive to changes in temperature. The temperature profiles are selected to satisfy critical dimension (CD) requirements and/or to maintain etch dimension uniformity for one or more features being formed during processing.

Temperatures of a substrate can be controlled actively and/or passively. A substrate processing system can include an active cooling system to adjust temperatures across a substrate during processing. The cooling system may include a temperature-controlled reservoir, a pump and coolant lines and one or more cooling channels. The cooling channels are disposed within the substrate support. A controller controls the pump to adjust flow and temperature of coolant to and from the one or more cooling channels via the coolant lines, which adjusts a temperature of the substrate being processed. In order to passively control a temperature profile of the substrate, various structural aspects of the cooling channels may be preselected, such as dimensions, shapes, locations, layout patterns, and number of cooling channels.

An increase in RF power requirements for a etch process can result in an increase in heat load on a substrate. This requires additional cooling capacity from a substrate support. In addition, lower substrate temperatures can provide benefits in advanced applications such as high aspect ratio etch operations. In order to provide reduced temperatures, additional thermal energy (or heat) needs to be extracted from the substrate support. This also requires additional cooling capacity of a substrate support. The relationship between heat load W, substrate temperature Tₛ, coolant temperature T_{fluid}, a heat transfer coefficient U, a surface area A of cooling channel, a mass flow rate m, heat capacity Cₚ, and change in coolant temperature ΔT_{fluid}, IS provided by equation 1. A product of the heat transfer coefficient U and the cooling area A refers to the cooling capacity of the substrate support.

$$W = U A ( {T}_{s} - {T}_{fluid} ) = \dot{m} {C}_{p} \cdot {ΔT}_{fluid} \qquad ( 1 )$$

As heat load W increases and mass flow rate m is constant, the rise in coolant temperature ΔT_{fluid} increases. As a coolant flows through a cooling channel, heat from the substrate support is extracted and the temperature of the coolant increases. Thus, depending on the layout of the channel, the cooling channel may provide a non-uniform temperature profile.

A traditional cooling channel of a substrate support having a single inlet and a single outlet has limited cooling. Traditional cooling channels have rectangular-shaped cross-sections with widths and heights that are uniform along the lengths of the channels. The cross-section of a channel refers to a cross-sectional slice taken across the channel perpendicular to a length and/or longitudinal centerline of the channel, where the longitudinal centerline extends from the inlet of the channel to the outlet of the channel. The plane of the cross-sectional slice does not extend longitudinally along and/or parallel to the longitudinal centerline. The widths and heights are each typically greater than or equal 6 millimeters (mm), such that each of the areas of the cross-sections is greater than or equal to 36 mm². The cooling capacity is limited by the rate at which coolant is able to be passed through the cooling channel. In order to increase cooling capacity UA, fluid flow rate can be increased. The fluid flow rate is limited by pressure drop across the cooling channel. The higher the fluid flow rate, the higher the pressure drop across the cooling channel. The fluid flow rate through the cooling channel is directly related to the pressure drop across the cooling channel. Also, in order to provide a higher pumping pressure, a larger capacity pump is needed, which increases pumping costs. Thus, velocity of fluid flow through traditional cooling channel arrangements is limited and as a result corresponding cooling capacities are also limited.

The examples set forth herein include substrate supports with with mesochannel assemblies that provide increased cooling over substrate supports having traditional cooling channels. Each of the disclosed substrate supports includes one or more layers of mesochannels. A mesochannel may refer to a microchannel or a minichannel. A mesochannel may have a cross-section with a hydraulic diameter Dh of less than or equal to 3.0 mm. The cross-section may be of various shapes. In some embodiments, the cross-sections are rectangular-shaped having corresponding widths and heights. In some embodiments, the mesochannels have cross-sections with hydraulic diameters Dh of less than or equal to 1.5 mm. In other embodiments, the mesochannels have cross-sections with hydraulic diameters Dh of less than or equal to 1.0 mm. A microchannel may have a cross-section with a hydraulic diameter Dh of less than or equal to 200 μm. A minichannel may have a cross-section a hydraulic diameter Dh of less than or equal to 3.0 mm. In some embodiments, a microchannel has a cross-section with a hydraulic diameter Dh greater than 10 μm and less than or equal to 200 μm. In some embodiments, a minichannel has a cross-section with a hydraulic diameter Dh greater than 200 μm and less than or equal to 3.0 mm. Any of the mesochannels referred to herein may be implemented as a microchannel or as a minichannel.

The use of the term “micro” does not necessarily mean that the corresponding cross-sections have widths, heights, and/or hydraulic diameters that are on a micro scale (i.e., less than 1 mm). However, the microchannels may have cross-sections with widths, heights and cross-sections that are each less than 1 mm. Each of the mesochannels performs as a heat exchanger by extracting thermal energy from the substrate support body and transferring the thermal energy to a coolant in the mesochannels.

The microchannels have high heat transfer coefficients (e.g., three to four times higher than compared to conventional channels) and have a high surface to volume ratio. Microchannels are suited for applications requiring a compact design. The small cross-sectional profiles of the microchannels provide design versatility because the microchannels may be incorporated in different plates and/or portions of a body of a substrate support to provide different temperature profiles.

Each of the substrate supports may include one or more pairs of manifolds, where each pair of manifolds includes a supply manifold and a return manifold. Each pair of manifolds is connected to a respective set of mesochannels. Each pair of manifolds and corresponding set of mesochannels are fluidically connected to perform as a single heat exchanger (referred to herein as a microchannel heat exchanger). Mesochannels refer to channels that are connected in parallel between a same pair of manifolds such that there are two or more parallel paths. This is unlike conventional channels, which do not extend between manifolds and are stand alone single channels having a single path for fluid flow with a respective input and output. A conventional substrate support typically includes only one conventional channel.

Some of the examples minimize temperature variations laterally across a substrate support. This includes minimizing variations point-to-point. The disclosed examples include mesochannel assemblies, which minimize temperatures of cooling fluid while maintaining the cooling fluid at nearly uniform temperatures across a substrate support. Other examples provide predetermined temperature profiles with varying temperatures radially across the substrate support.

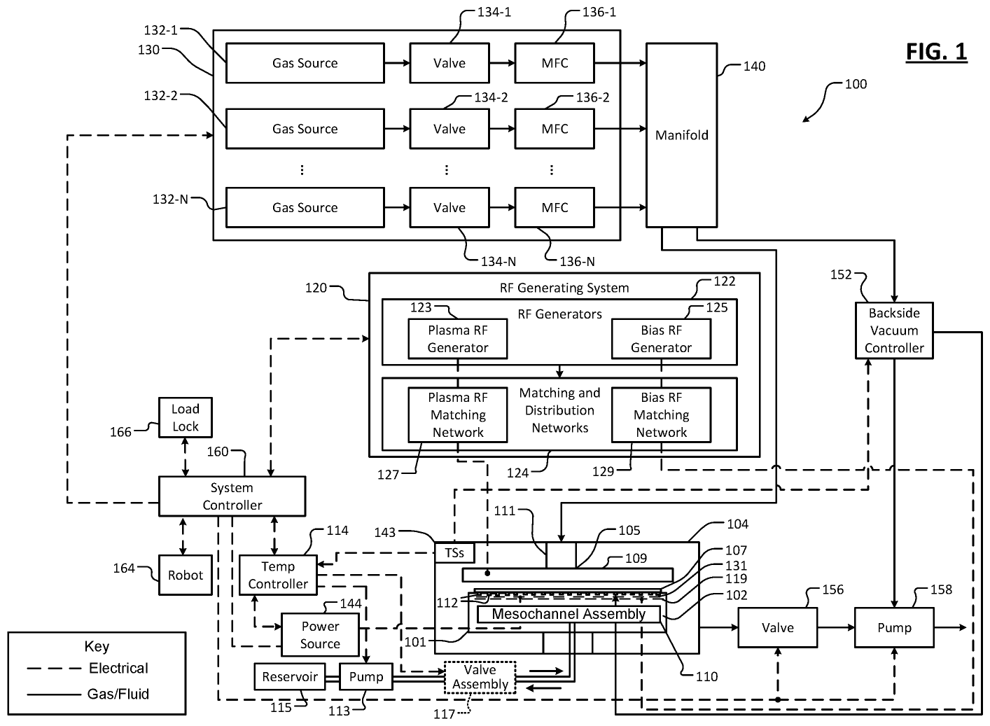

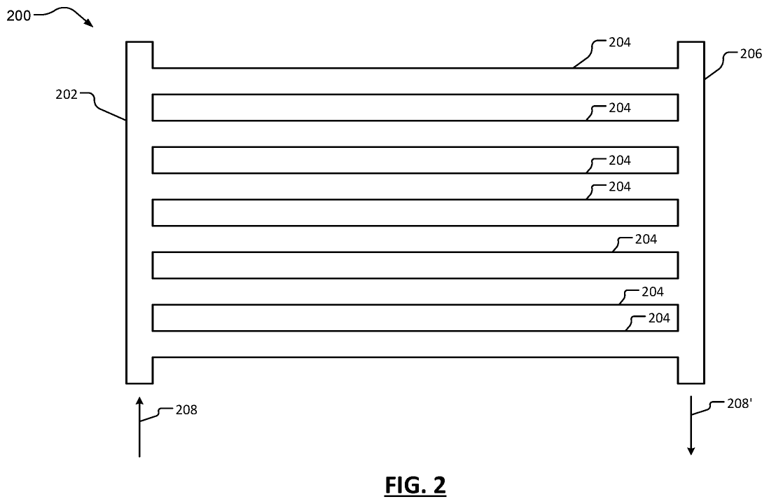

FIG. 1 shows an example substrate processing system 100 including a substrate support 101, shown as an electrostatic chuck. The substrate support 101 may be configured the same or similarly as any of the substrate supports disclosed herein including that shown in FIGS. 2-15B and/or include one or more aspects thereof. Although FIG. 1 shows a capacitive coupled plasma (CCP) system, the embodiments disclosed herein are applicable to transformer coupled plasma (TCP) systems, inductively coupled plasma (ICP) systems and/or other processing systems and plasma sources that include a substrate support. The embodiments are applicable to dry etch processing systems and other processing systems including a substrate support. In the example shown, the substrate support 101 includes a body 102. The body 102 may be formed of different materials and/or different ceramic compositions. The body 102 may include, for example, aluminum alloy, aluminum nitride (AlN₃), aluminum oxide (Al₂O₃), and/or aluminum oxynitride (AlON).

The substrate processing system 100 includes a processing chamber 104. The substrate support 101 is enclosed within the processing chamber 104. The processing chamber 104 also encloses other components, such as an upper electrode 105, and contains RF plasma. During operation, a substrate 107 is arranged on and electrostatically clamped to the substrate support 101. For example only, the upper electrode 105 may include a showerhead 109 that introduces and distributes gases. The showerhead 109 may include a stem portion 111 including one end connected to a top surface of the processing chamber 104. The showerhead 109 is generally cylindrical and extends radially outward from an opposite end of the stem portion 111 at a location that is spaced from the top surface of the processing chamber 104. A substrate-facing surface of the showerhead 109 includes holes through which process or purge gas flows. Alternately, the upper electrode 105 may include a conducting plate and the gases may be introduced in another manner. In an embodiment, the substrate support 101 may include one or more gas channels 112 for flowing backside gas to a backside of the substrate 107.

The substrate support 101 may include a mesochannel assembly 110, which receives a coolant from a pump 113. A temperature controller 114 controls operation of the pump 113 to control flow and temperature of coolant to and from the mesochannel assembly 110. The pump 113 may circulate coolant between a reservoir 115 and the mesochannel assembly 110. Although a single pump 113 is shown, two or more pumps may be included. In one embodiment, the mesochannel assembly 110 includes a single coolant input and a single coolant output. In another embodiment, the mesochannel assembly 110 includes multiple coolant inputs and coolant outputs. A valve assembly 117 may be disposed between the pump 113 and the mesochannel assembly 110 and be controlled by the temperature controller 114. A pair of supply and return lines may be connected (i) between the one or more pumps and the mesochannel assembly 110, and/or (ii) between the valve assembly 117 and the mesochannel assembly 110. Examples of the mesochannel assembly 110 are further described below with respect to FIGS. 2-15B.

An RF generating system 120 generates and outputs RF voltages to the upper electrode 105 and one or more lower electrodes 119 in the substrate support 101. One of the upper electrode 105 and the substrate support 101 may be DC grounded, AC grounded or at a floating potential. For example only, the RF generating system 120 may include one or more RF generators 122 (e.g., a capacitive coupled plasma RF power generator, a bias RF power generator, and/or other RF power generator) that generate RF voltages, which are fed by one or more matching and distribution networks 124 to the upper electrode 105 and/or the substrate support 101. An electrode that receives an RF signal, an RF voltage and/or RF power is referred to as a RF electrode. As an example, a plasma RF generator 123, a bias RF generator 125, a plasma RF matching network 127 and a bias RF matching network 129 are shown. The plasma RF generator 123 may be a high-power RF generator producing, for example, 6-10 kilo-watts (KW) of power or more. The bias RF matching network supplies power to RF electrodes, such as RF electrodes 119.

A gas delivery system 130 includes one or more gas sources 132-1, 132-2, . . . , and 132-N (collectively gas sources 132), where N is an integer greater than zero. The gas sources 132 supply one or more precursors and gas mixtures thereof. The gas sources 132 may also supply etch gas, carrier gas and/or purge gas. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 104. For example only, the output of the manifold 140 is fed to the showerhead 109.

Although shown separately from a system controller 160, the temperature controller 114 may be implemented as part of the system controller 160. The substrate support 101 may include multiple temperature controlled zones, where each of the zones includes a temperature sensor and a set of microchannels. The temperature controller 114 may monitor temperatures as indicated by the temperature sensors and adjust flow rate and/or temperature of coolant circulating through the one or more sets of microchannels to adjust the temperatures to target temperatures.

The substrate processing system 100 may also include a power source 144 that provides power, including a high voltage, to clamping electrodes 131 to electrostatically clamp the substrate 107 to the substrate support 101. Clamping electrodes receive power to electrostatically clamp down the substrate 107 to the substrate support 101 and may receive RF signals, RF voltages and/or RF power. The power source 144 may be controlled by the system controller 160.

The substrate processing system 100 may further include a backside vacuum controller 152. The backside vacuum controller 152 may receive gas from the manifold 140 and supply the gas to the channels 112 and/or to a pump 158. This improves transfer of thermal energy between the substrate support 101 and the substrate 107. The backside gas may also be provided to improve substrate peripheral edge purging and vacuum tracking of a location of the substrate. The channels 112 may be fed by one or more injection ports. In one embodiment, multiple injection ports are included for improved cooling. As an example, the backside gas may include helium.

The temperature controller 114 may control operation of the pump 113 and/or other coolant circulating pumps and/or the valve assembly 117 based on detected parameters from temperature sensors 143 within the processing chamber 104. The backside vacuum controller 152 controls flow rate of backside gas (e.g., helium) to the channels 112 for cooling the substrate 107 by controlling flow from one or more of the gas sources 132 to the channels 112. The backside vacuum controller 152 controls pressure and flow rates of gas supplied to channels 112 based on detected parameters from the temperature sensors 143. In one embodiment, the temperature controller 114 and the backside vacuum controller 152 are implemented as a combined single controller.

The temperature sensors 143 may include resistive temperature devices, thermocouples, digital temperature sensors, and/or other suitable temperature sensors. One or more of the temperatures sensors 143 may be disposed in and be used to detect temperatures of the substrate support 101. During a deposition process, the substrate 107 may be heated in presence of high-power plasma. Flow of gas through the channels 112 may reduce temperatures of the substrate 107.

A valve 156 and the pump 158 may be used to evacuate reactants from the processing chamber 104. The system controller 160 may control components of the substrate processing system 100 including controlling supplied RF power levels, pressures and flow rates of supplied gases, RF matching, etc. The system controller 160 controls states of the valve 156 and the pump 158. A robot 164 may be used to deliver substrates onto, and remove substrates from, the substrate support 101. For example, the robot 164 may transfer substrates between the substrate support 101 and a load lock 166. The robot 164 may be controlled by the system controller 160. The system controller 160 may control operation of the load lock 166.

The valves, gas pumps, power sources, RF generators, etc. referred to herein may be referred to as actuators. The microchannels, gas channels, etc. referred to herein may be referred to as temperature adjusting elements.

The substrate support 101 may have a stacked structure with multiple plates as further described below. As an example, the substrate support 101 may include multiple plates and/or layers including one or more microchannel layers, one or more crossover layers, manifold layers, intermediate layers, etc. Makeup and materials of the layers are further described below.

In the example shown, the electrodes 119, 131 are disposed in an uppermost one of the layers. The mesochannel assembly 110 is disposed in another one or more of the layers. Although a single microchannel assembly is shown, the body 102 may include any number of mesochannel assemblies disposed in any number of mesochannel layers, where each layer may include any number of mesochannels having various sizes, shapes, layout patterns, and dimensions.

Although each of the following substrate supports of FIGS. 2-15B are each shown as having certain features and not other features, each of the substrate supports may be modified to include any of the features described herein and shown in FIGS. 2-15B.

FIG. 2 shows a microchannel assembly 200 that may be disposed within a substrate support and includes a supply (or input) manifold 202, mesochannels 204 and a return (or output) manifold 206. The supply manifold 202 receives coolant 208. The coolant 208 passes through the supply manifold 202 to the mesochannels 204 and then to the return manifold 206. The mesochannels 204 may extend in a parallel arrangement, as shown, or in a winding, bending and/or circular arrangement. The output of the return manifold is coolant 208′, which is at an increased temperature as compared to the received coolant 208. The microchannels 204 facilitate flow of coolant from the supply manifold 202 to the return manifold 206.

The manifolds 202, 206 may be in different locations and away from each other as shown or may be disposed in a close arrangement, wherein the manifolds are near each other. Various other manifold arrangements are described below. The manifolds may be disposed near or away from each other. The manifolds may be disposed to provide a center hot or edge hot arrangement. The phrase “center hot” refers to a center of a substrate support. The phrase “edge hot” refers to an outer circumferential edge of a substrate support.

The mesochannels 204 provide increased surface area for extracting thermal energy from surrounding material of the substrate support. By providing an increased number of smaller channels, the mesochannels 204 collectively have more external channel surface area than a signal traditional channel. The thermal energy is transferred to the coolant 208 passing through the mesochannels 204. The mesochannels 204 have a higher surface to volume ratio and an increased heat transfer coefficient U, as compared to traditional cooling channels. By providing an increased number of channels, there is an increased number of channel sides, which corresponds to an increased amount of surface area. The sum of the surface areas of the sides of the mesochannels 204 is more than that of a traditional channel. Although the collective volume of the mesochannels 204 may be less than the volume of a single traditional channel, the mesochannels 204 have increased surface area and provide the same or more cooling than a traditional channel. The collective surface area to volume ratio of the mesochannels 204 is much higher than a traditional channel. The heat transfer coefficient U is a function of fluid flow velocity. The smaller the cross-sectional area of the channel, generally the higher the velocity of coolant passing through the channel. Since the mesochannels 204 have a small cross-sectional area, the velocity of fluid flow is increased and thus the heat transfer coefficient is increased. The heat transfer coefficient U of the mesochannel assembly 200 may be, for example, twice that of a conventional cooling channel. The mesochannels 204 provide increased cooling capacity UA while exhibiting similar fluid pressure drops between inputs and outputs of the mesochannels 204. Depending on the design, the pressure drops may be slightly higher or slightly lower than traditional cooling channels.

If the same heat load is provided using a conventional cooling channel as provided using a mesochannel assembly 200, then the driving temperature differential between the substrate support and the fluid for the mesochannel assembly 200 is much less than the temperature differential of the conventional cooling channel to achieve the same substrate temperatures. The mesochannels 204 may provide 2-3 times more heat transfer than a conventional cooling channel arrangement. This allows fluid inlet temperature for a mesochannel 204 to be much higher than for conventional channels, for the same substrate temperature. A conventional channel requires fluid temperature to be as low as −60° C. to −100° C. for certain processes. With a mesochannel 204, this coolant temperature may be brought up to −30° C. to −70° C., greatly reducing the need of cryogenic temperature control at the pump end. The capacity of the pump is greater than a predetermined minimum capacity to assure that the flow rate is greater than a predetermined minimum flow rate to prevent coolant temperatures from exceeding predetermined maximum temperatures. If the flow rate is too slow, then the temperatures across the substrate support can exceed set maximum temperature thresholds.

The mesochannels 204 disclosed herein may operate in a single-phase mode or in a dual-phase mode. The single-phase mode refers to when the coolant flowing through the mesochannels 204 remains in a liquid state. The dual-phase mode refers to when the coolant flowing through the mesochannels 204 changes between a liquid state and a gas state. Latent heat occurs when the coolant transitions between liquid and gas states. Mesochannels 204 have approximately 70% less volume for a same amount of heat load as conventional cooling channels. The heat transfer coefficient U may increase 100% without boiling as compared to a conventional channel. The heat transfer coefficient U may increase greater than 300% with boiling as compared to a conventional channel.

As described above, the cross-sections of the mesochannels 204 are small (e.g., hydraulic diameter Dh of less than 3.0 mm), which provides a structure with design versatility. As an example, a width or height may be less than or equal to 4 mm when the hydraulic diameter Dh is 2.0 mm. Mesochannel assemblies may be incorporated in a substrate support and/or portions thereof in various arrangements. The mesochannel assemblies may be located in various locations and in one or more layers while allowing space for other components. A mesochannel assembly may be incorporated into, for example, a cold plate. In one embodiment, a first plate is machined to form mesochannel grooves (three sides of the microchannels) and a second plate is attached to the first plate and provides the fourth sides of the mesochannels. Vacuum brazing may be implemented to join the second plate to the first plate. The second plate may be sealed and/or bonded to the first plate. In another embodiment, the mesochannels are formed using additive manufacturing techniques. In addition to brazing, three-dimensional (3D) printing may be implemented to form at least portions of the mesochannel assemblies disclosed herein.

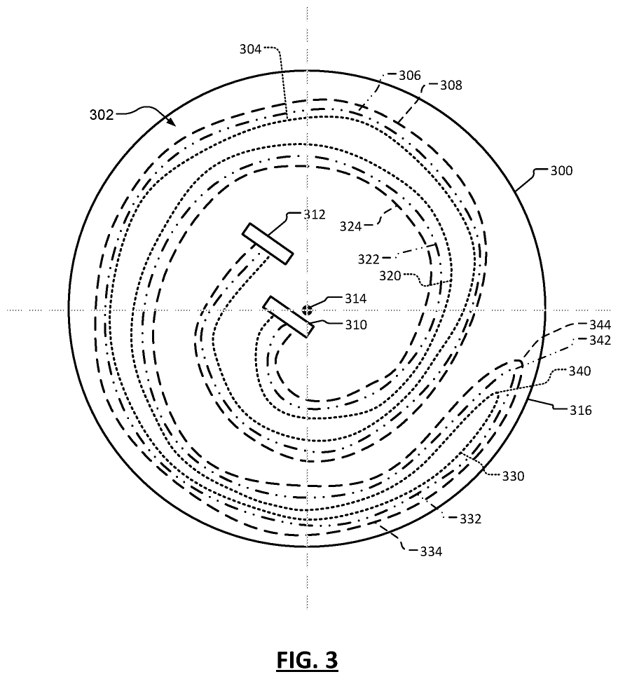

FIG. 3 shows a portion 300 of an example substrate support. The portion 300 may include multiple stacked plates, which include a mesochannel assembly 302 with multiple spiral-shaped mesochannels 304, 306, 308. A supply manifold 310 receives coolant, which flows from the supply manifold 310 to the mesochannels 304, 306, 308. The coolant flows from the mesochannels 304, 306, 308 to a return manifold 312. The mesochannels 304, 306, 308 are spiral-shaped and the manifolds 310, 312 are disposed adjacent each other to provide a temperature averaging effect for improved uniform cooling laterally across the substrate support. Although three mesochannels are shown, a different number of mesochannels may be included. The mesochannels 304, 306, 308 extend in a parallel manner starting from the supply manifold 310 near a center 314 of the substrate support and spiraling towards a circumferential outer edge 316 of the substrate support. The mesochannels 304, 306, 308 then extend in a spiraling manner back from the circumferential outer edge 316 to the return manifold 312 near the center 314 of the substrate support.

The mesochannels 304, 306, 308 may exhibit a 2-3 times higher overall heat transfer coefficient compared to conventional cooling channels. In one embodiment, the cross-sections and lengths of the mesochannels 304, 306, 308 are approximately the same and/or within predetermined ranges of each other. In one embodiment, the winding arrangement and paths of each of the mesochannels 304, 306, 308 are set such that the lengths are the same. As a result, the heat transfer coefficients of the mesochannels 304, 306, 308 are the same or within a predetermined range of each other.

The coolant flowing through the mesochannels increases in temperature as it travels from the supply manifold 310 to the return manifold 312. The mesochannels 304, 306, 308 include first portions 320, 322, 324, which spiral outward, starting from the supply manifold 310, towards the circumferential outer edge 316, and second portions 330, 332, 334, which spiral inward towards the center 314 and the return manifold 312. Since the first portions 320, 322, 324 extend parallel to the second portions 330, 332, 334 of the mesochannels 304, 306, 308, temperatures are averaged to provide a more uniform temperature profile. The first portions 320, 322, 324 transition to the second portions 330, 332, 324 at vertices 340, 342, 344. The mesochannels 304, 306, 308 provide increased cooling for reduced substrate support process temperature.

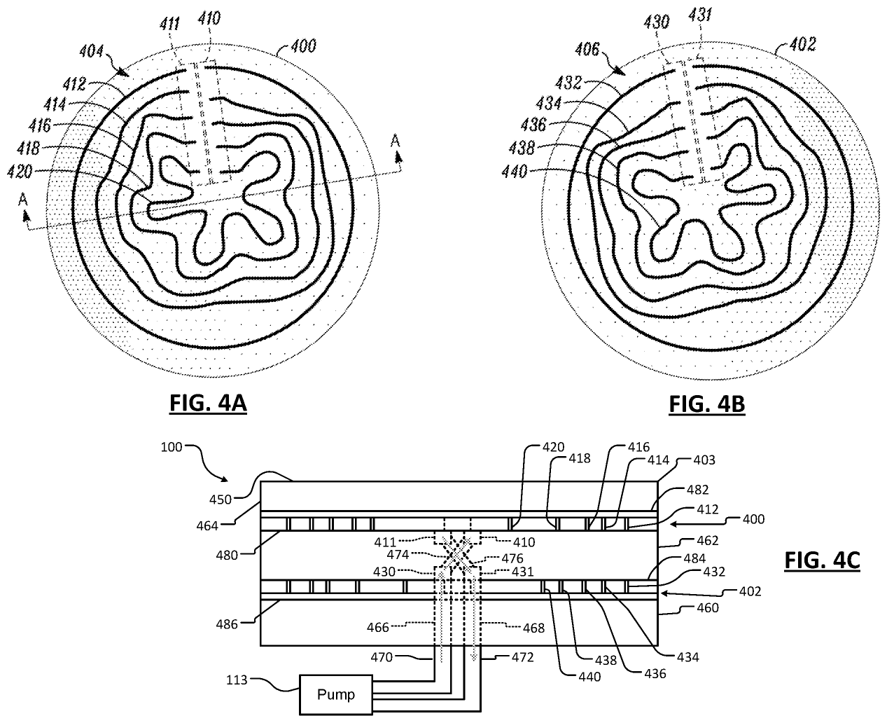

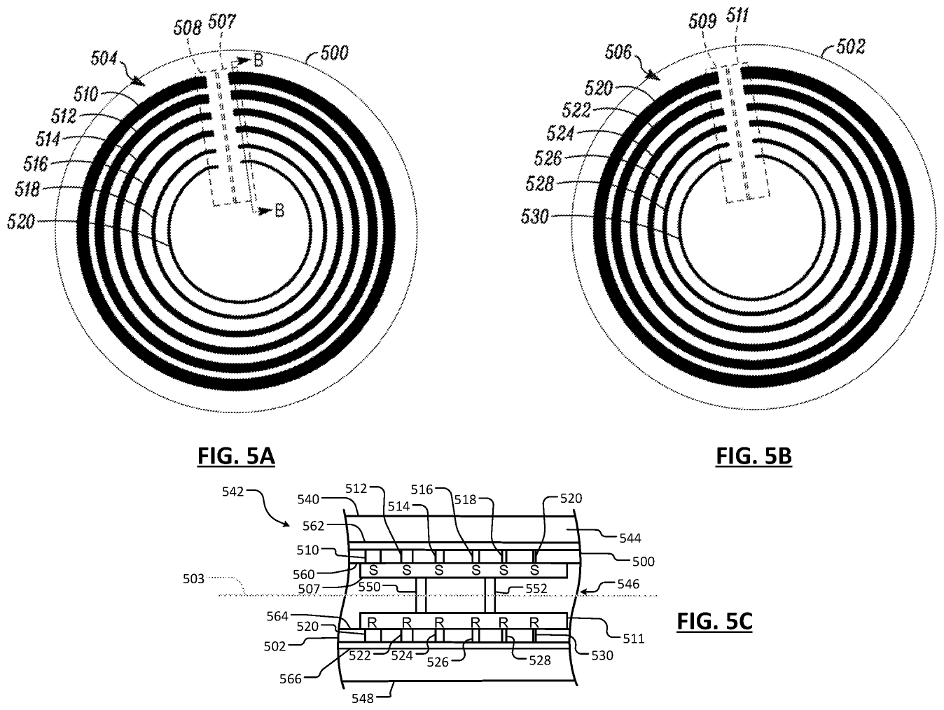

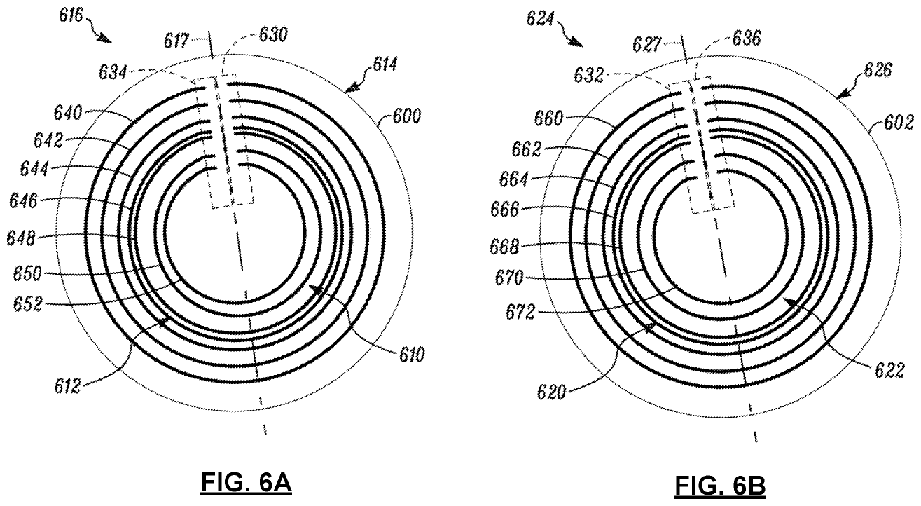

FIGS. 4A and 4B show a first mesochannel layer 400 and a second microchannel layer 402 of an example substrate support 403, which is shown in FIG. 4C. The first mesochannel layer 400 includes a first mesochannel assembly 404 and the second mesochannel layer 402 includes a second mesochannel assembly 406. The first mesochannel assembly 404 includes a supply manifold 410, a return manifold 411 and concentric mesochannels 412, 414, 416, 418, 420. The second mesochannel assembly 406 includes a supply manifold 430, a return manifold 431 and concentric mesochannels 432, 434, 436, 438, 440. The first mesochannel layer 400 may be disposed above the second mesochannel layer 402 in a stacked arrangement, as shown in FIG. 4C. Coolant flows in an opposite direction in the second mesochannel layer 402 than in the first mesochannel layer 400. As a result, there is a temperature averaging effect provided by the combination of the mesochannel layers 400, 402. Dot patterns are provided In FIGS. 4A, 4B to illustrate differences in temperatures across the layers 400, 402. On the first mesochannel layer 400 the number of dots increase per unit area from right to left to represent an increase in temperature. Similarly, on the second mesochannel layer 402, the number of dots increase per unit area from left to right to represent a decrease in temperature. Although on each of the layers 400, 402, three dot patterns are shown, in actuality the increase in temperature is gradual across the layers 400, 402 and not stepped or incrementally increased. Similar temperature patterns may exist in the mesochannel layers of, for example, FIGS. 5A, 5B, 6A, and 6B, although not shown. The return manifold 411 may be disposed above the supply manifold 430. Similarly, the supply manifold 410 may be disposed above the return manifold 431.

The mesochannels 412, 414, 416, 418, 420 and the mesochannels 432, 434, 436, 438, 440 extend across respective mesochannel layers 400 and 402 once, meaning that the mesochannels do not each include parallel extending portions, as do the mesochannels of FIG. 3. In one embodiment, mesochannels 412, 414, 416, 418, 420 and the mesochannels 432, 434, 436, 438, 440 have different winding patterns and paths, but yet have a same length. By having mesochannels with equivalent lengths and cross-sectional areas, the resistance and pressure drop along the lengths of the mesochannels are the same, which provides the same flow distribution and causes the temperatures of coolant in the mesochannels to be the same or similar. The radially inward mesochannels, such as the mesochannels 418, 420, 438, 440 have more bends and the bends are sharper than the outer mesochannels, such as the mesochannels 412, 414, 432, 434. In order to fit a first mesochannel that is the same length as a second mesochannel in a smaller area than an area in which the second mesochannel is disposed, the first mesochannel includes more, sharper and/or larger bends than the second mesochannel. The sharper the bends, the higher the flow resistance.

The mesochannels 412, 414, 416, 418, 420 and the mesochannels 432, 434, 436, 438, 440 may provide 2-3 times higher overall heat transfer coefficient than a conventional cooling channel. Since the cross-section and length of the mesochannels 412, 414, 416, 418, 420 and the mesochannels 432, 434, 436, 438, 440 may be the same or nearly the same, the heat transfer coefficient across the layers 400, 402 are the same or nearly the same.

Each of the layers 400, 402 includes mesochannels with fluid increasing in temperature from supply manifolds to return manifolds, which results in a unidirectional temperature non-uniformity. This is compensated by having multiple mesochannel layers stacked to average out the overall temperatures and results in a more uniform temperature distribution laterally across a top surface 450 of the substrate support 403. The structure of the substrate support 403 may be achieved, for example, using additive manufacturing. The resulting structure provides increased cooling with low substrate support process temperatures. Increased temperature uniformity increases substrate processing yields.

When providing uniform cooling laterally across the substrate support 403, to compensate for non-uniformities in temperature, which are not fully compensated for by the arrangement of bends in the mesochannels, cross-sections of one or more of the mesochannels may be modified. This may include changing the dimensions and/or patterns of the cross-sections. The cross-sections of a mesochannel refer to planar sections taken perpendicular to the path direction of the mesochannel and the dimensions and shape of the cross-section. For example, if a mesochannel is a rectangular-shaped channel, a cross-section of the mesochannel would be a rectangle having a width and a height, which may be modified to adjust a temperature in a location of the cross-section. As another example, an innermost mesochannel loop may have a different (e.g., smaller or larger) cross-section than an outermost mesochannel loop. The mesochannels in each of the layers 400, 402 may be referred to as mesochannel loops.

In one embodiment, the lengths, cross-sectional areas, dimensions, gaps between mesochannels, sharpness of bends, and/or layout patterns of one or more of the mesochannel layers 400, 402 are different to provide a predetermined temperature distribution profile. The temperature distribution profile may not be uniform and/or may be set to provide increased cooling in one or more areas of the substrate support.

FIG. 4C shows the substrate support 403 including the mesochannel layers 400, 402. The substrate support 403 may further include a base layer 460, an intermediate layer 462 and a top layer 464. The base layer 460 may include channels 466, 468 through which coolant passes between lines 470, 472 and manifolds 430, 431 in the intermediate layer 462. Coolant channels 466, 468 may be included in the substrate support 403 and used to transfer coolant to and from the manifolds 430, 431. The coolant channels 466, 468 may extend through the mesochannel layer 402 and base layer 460. In another embodiment, the lines 470, 472 extend, for example, to and from a side of the substrate support 403 and connect to the manifolds 430, 431 via laterally extending channels that extend from an outer circumferential edge of the substrate support 403 to ends of the manifolds 430, 431. A single point of contact (POC) is provided by the single pair of lines 470, 472 that supply coolant to and receive the coolant from the mesochannel assemblies 404, 406. Each of the substrates supports described herein may include one or more POCs, where each POC includes a pair of supply and return lines. Each of the POCs may be used to supply and receive coolant from one or more mesochannel assemblies.

Coolant may be supplied to the manifold 430 via the coolant channel 466 and/or line 470 and the pump 113 and return to the pump 113 via the coolant channel 468 and/or line 472. Coolant flows from the manifold 430 to (i) the mesochannels 432, 434, 436, 438, 440, and (ii) a first crossover channel 474. The first crossover channel 474 guides coolant to the supply manifold 410. Although two crossover channels are shown, additional crossover channels may be included and connected to the manifolds 410, 411, 430, 431. Coolant from the supply manifold 410 passes through the mesochannels 412, 414, 416, 418, 420 and then returns via the return manifold 411. The coolant then flows from the return manifold 411 to a second crossover channel 476 and then to the return manifold 431. Coolant also returns from the mesochannels 432, 434, 436, 438, 440 to the return manifold 431. The coolant in the return manifold 431 may return to the pump 113 or a reservoir via the line 472.

The mesochannel layers 400, 402 may each include a pair of plates (or layers). For example, the mesochannel layer 400 may include a first plate 480 and a second plate 482. Grooves may be cut in the first plate 480 to form sides of the mesochannels 412, 414, 416, 418, 420. The second plate 482 and the intermediate layer 462 may provide top and bottom surfaces of the mesochannels 412, 414, 416, 418, 420. The plates 480, 482 may be formed as a single plate. The plate 480 defines the sides of the mesochannels 412, 414, 416, 418, 420. The second mesochannel layer 402 may include a first plate 484 and a second plate 486. Grooves may be cut in the first plate 484 to form sides of the mesochannels 432, 434, 436, 438, 440. The second plate 486 and the intermediate layer 462 may provide top and bottom surfaces of the mesochannels 432, 434, 436, 438, 440. The plates 484, 486 may be formed as a single plate. The plate 484 defines the sides of the mesochannels 432, 434, 436, 438, 440. The plates 480, 482 may be attached and the plates 484, 486 may be attached using the above-described methods. Additional mesochannel layers and crossover layers may be included and arranged similarly as and stacked with the layers 400, 402, 462.

Gaps between the mesochannels 412, 414, 416, 418, 420 and the mesochannels 432, 434, 436, 438, 440 may be adjusted to provide more uniform heating across the substrate support 403. For example, in areas where there is more mesochannel bending, the mesochannels may be further spaced apart, than in areas where there is less mesochannel bending. The layout pattern of the mesochannels 412, 414, 416, 418, 420 may be the same or different than the layout pattern of the mesochannels 432, 434, 436, 438, 440. In one embodiment, the layout pattern of the mesochannels 432, 434, 436, 438, 440 is a mirror image of the mesochannels 412, 414, 416, 418, 420. Although each of the mesochannel layers 400, 402 includes five mesochannels, each of the mesochannel layers 400, 402 may include a different number of mesochannels.

FIGS. 5A and 5B show a first mesochannel layer 500 and a second mesochannel layer 502. The mesochannel layers 500, 502 may be symmetrical with respect to a plane 503 extending laterally between the layers 500, 502. The mesochannel layers 500, 502 may not be symmetrical, but yet still have opposite temperature distribution profiles to provide an overall uniform temperature distribution profile. The mesochannel layers 500, 502 include respective mesochannel assemblies 504, 506. The first mesochannel assembly 504 includes a supply manifold 507, a return manifold 508, and mesochannels 510, 512, 514, 516, 518, 519. The second mesochannel assembly includes a supply manifold 509, a return manifold 511 and mesochannels 520, 522, 524, 526, 528. The mesochannels 510, 512, 514, 516, 518, 519 are concentric and annular-shaped and extend laterally across the mesochannel layer 500 once. The mesochannels 520, 522, 524, 526, 528 are concentric and annular-shaped and extend laterally across the mesochannel layer 502 once. In this embodiment, the cross-sections of the mesochannels increase in size the more radially outward the corresponding mesochannel is disposed. For example, the mesochannels 510, 512, 514, 520, 522, 524 have larger width cross-sections than the mesochannels 516, 518, 519, 526, 528, 530. The longer the mesochannel, the larger the cross-section. As an example, the size of the cross-section may refer to the area of the cross-section.

The mesochannel assemblies 504, 506 have 2-3 times higher an overall heat transfer coefficient than a conventional cooling channel. Since a flow rate of coolant through each of the mesochannels 510, 512, 514, 516, 518, 519, 520, 522, 524, 526, 528 is the same or similar, the heat transfer coefficient across the corresponding layers 500, 502 is the same or similar. Also, since the coolant increases in temperature when moving through the mesochannels 510, 512, 514, 516, 518, 519, 520, 522, 524, 526, 528 from the supply manifolds 507, 509 to the return manifolds 508, 511, a unidirectional temperature non-uniformity exists in each of the layers 500, 502. This is compensated for by having multiple layers of mesochannels stacked together to average out overall temperature and result in uniform temperature distribution laterally across a top surface 540 of the corresponding substrate support, shown in FIG. 5C. The resulting structure provides increased cooling with low substrate support process temperatures. Increased temperature uniformity increases substrate processing yields.

FIG. 5C shows a portion 542 of the substrate support and includes the mesochannel layers 500, 502, a top layer 544, an intermediate layer 546, and a base layer 548. The intermediate layer 546 includes the manifolds 507, 508, 509, 511 and two or more crossover channels (two crossover channels 550, 552 are shown). The mesochannel layers 500, 502 include plates 560, 562, 564, 566 and the mesochannels 510, 512, 514, 516, 518, 519, 520, 522, 524, 526, 528.

FIGS. 6A and 6B show portions 600, 602 of an example substrate support including multiple zones of mesochannels. The portions 600, 602 include respective mesochannel layers including respective mesochannel assemblies. The mesochannel layers may be symmetrical with respect to a plane extending laterally between the layers, similar to the plane 503 shown in FIG. 5C. The mesochannel layers may not be symmetrical, but yet still have opposite temperature distribution profiles to provide an overall uniform temperature distribution profile. The portion 600 may be stacked above the portion 602. For example, each of the portions 600, 602 includes multiple zones. The portion 600 includes an inner cold zone 610, an inner intermediate zone 612, an outer intermediate zone 614 and an outer hot zone 616. The zones 614 and 616 refer to hemi-spherical portions of the corresponding mesochannel layer of the substrate support on either side of centerline 617. The portion 602 includes an inner cold zone 620, an inner intermediate zone 622, an outer intermediate zone 624, and an outer hot zone 626. The zones 624 and 626 refer to hemi-spherical portions of the corresponding mesochannel layer of the substrate support on either side of centerline 627. The centerline 627 may extend parallel to, in line with and below the centerline 617.

The portions 600, 602 include supply manifolds 630, 632 and return manifolds 634, 636. The portion 600 includes the mesochannels 640, 642, 644, 646, 648, 650, 652. The portion 602 includes the mesochannels 660, 662, 664, 666, 668, 670, 672.

More cooling may be provided where the mesochannels are more condensed (or closely arranged), such as near the mesochannels 644, 646, 648, 664, 666, 668. In the example shown, more cooling is provided in an intermediate annular area (e.g., area near mesochannels 644, 646, 648, 664, 666, 668) and less at an innermost annular (e.g., area near mesochannels 648, 650, 652, 668, 670, 672) and outermost annular areas (e.g., area near mesochannels 640, 642, 644, 660, 662, 664). In another embodiment, more cooling is provided near the outer circumferential edge of the substrate support. In yet another embodiment, more cooling is provided near the center of the substrate support. The amount of cooling in different annular areas may be set based on the spacing between adjacent mesochannels and the number of microchannels in the stated annular areas.

For the embodiment of FIGS. 6A-6B, the more radially inward the mesochannel, the shorter the mesochannel and thus the less the pressure drop along the mesochannel, the less resistance to flow, and the higher the coolant flow rate. This results in the radially inner mesochannels providing more cooling than the radially outer mesochannels.

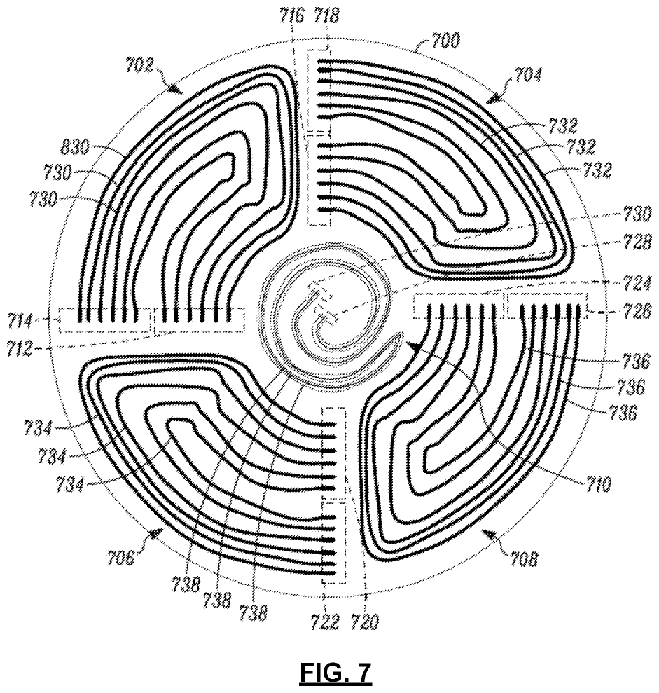

FIG. 7 shows a portion 700 of a substrate support including a layer with multiple zones 702, 704, 706, 708, 710 with respective dedicated pairs of manifolds. The zone 702 includes the manifolds 712, 714. The zone 704 includes the manifolds 716, 718. The zone 706 includes the manifolds 720, 722. The zone 708 includes the manifolds 724, 726. The zone 710 includes the manifolds 728, 730. In one embodiment, the manifolds 712, 716, 720, 724 and 728 are supply manifolds and the manifolds 714, 718, 722, 726 and 730 are return manifolds.

The zones 702, 704, 706, 708, 710 are independent zones that may be independently controlled. Each of the zones 702, 704, 706, 708, 710 has parallel extending mesochannels. The portion 700 has a 2-3 times higher overall heat transfer coefficient than a conventional cooling channel. By varying fluid flow in the zones 702, 704, 706, 708, 710, the heat transfer coefficient may be varied and controlled independently for each of the zones 702, 704, 706, 708, 710. Temperature uniformity may also be independently controlled via the zones 702, 704, 706, 708, 710. The zones 702, 704, 706, 708, 710 increase available substrate temperature tuning options. Each of the zones 702, 704, 706, 708, 710 may have the same, similar or different mesochannel layout patterns. The zones 702, 704, 706, 708, 710 include mesochannels, some of which designated respectively 730, 732, 734, 736, 738.

The mesochannels of the zones 702, 704, 706, 708, 710 may have same or different cross-sections. In the example shown, the mesochannels in the inner zone 710 have smaller cross-sections than the mesochannels in the zones 702, 704, 706, 708. Also, the inner zone 710 has fewer mesochannels than the zones 702, 704, 706, 708.

The lengths of the mesochannels in each of the zones 702, 704, 706, 708 may be different, as shown, or be the same. The lengths of the mesochannels of the inner zone 710 may be the same or similar, as shown, or be different. The lengths of the mesochannels in each zone may match or be different than the lengths of the mesochannels in the other zones. Each of the zones may have any number of mesochannels. Each zone may have a same number or a different number of mesochannels as the other zones.

The manifolds 712, 714, 716, 718, 720, 722, 724, 726 may be connected to respective supply and return lines and/or channels and thus have respective POCs. In one embodiment, the substrate support has a single POC, which (i) supplies coolant to a single primary supply manifold supplying coolant to first ones of the manifolds 712, 714, 716, 718, 720, 722, 724, 726 that are supply (or secondary) manifolds of the corresponding mesochannel assemblies, and (ii) receive coolant from a single primary return manifold receiving coolant from second ones of the manifolds 712, 714, 716, 718, 720, 722, 724, 726 that are return (or secondary) manifolds of the corresponding mesochannel assemblies.

A respective pump and/or one or more valves may be connected to each pair of supply and return manifolds of the distinct mesochannel assemblies of the zones. As an example, the temperature controller 114 of FIG. 1 may control operation of the one or more pumps and the states of the valves to independently control flow of coolant to and from each of the mesochannel assemblies.

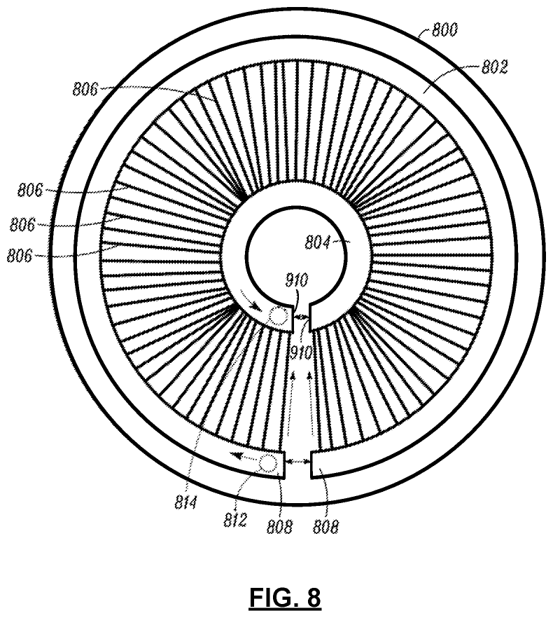

FIG. 8 shows a portion 800 of an example substrate support including non-continuous annular-shaped manifolds 802, 804 and uniform width mesochannels, some of which designated 806, which extend radially between the manifolds 802, 804. Any number of mesochannels may be included and the spacing between the mesochannels may be set to provide a predetermined temperature profile. The manifolds 802, 804 may be discontinuous as shown. The manifold 802 includes ends 808 with a gap G1 between the ends 808. The manifold 804 includes ends 810 with a gap G2 between the ends 810. The manifold 802 may include an input opening 812 and the manifold 804 may include an output opening 814. Coolant may be supplied via a channel to the input opening 812 and return via the output opening 814. The openings 812, 814 may be near ends of the manifolds 802, 804 or may be located at other positions along the manifolds 802, 804. Inclusion of a single input opening and a single output opening assures that fluid flows inside the manifolds in a single direction. If the manifolds 802, 804 were continuous, then fluid may flow in different directions causing fluid mixing and possibly reverse flow. This is prevented with the arrangement shown.

The supply manifold 802 may be located near an outer circumferential edge of the substrate support and the return manifold 804 may be located radially inward near a center of the substrate support as shown. In another embodiment, coolant flow is reversed, such that the manifold 804 performs as a supply manifold and the manifold 802 performs as a return manifold. As shown the coolant flows into the supply manifold 802, radially inward through the microchannels, and the out the return manifold 804.

The portion 800 has a 2-3 times higher overall heat transfer coefficient than a conventional cooling channel. In an embodiment, the cross-sections of the mesochannels are the same and thus the heat transfer coefficients of the mesochannels are the same. Since the mesochannels extend radially and in a linear manner, the lengths of the mesochannels are short. By including short mesochannels, the change in temperature of the coolant in the mesochannels is significantly reduced as compared to other arrangements having longer mesochannels. Increased cooling reduces substrate temperatures during processing.

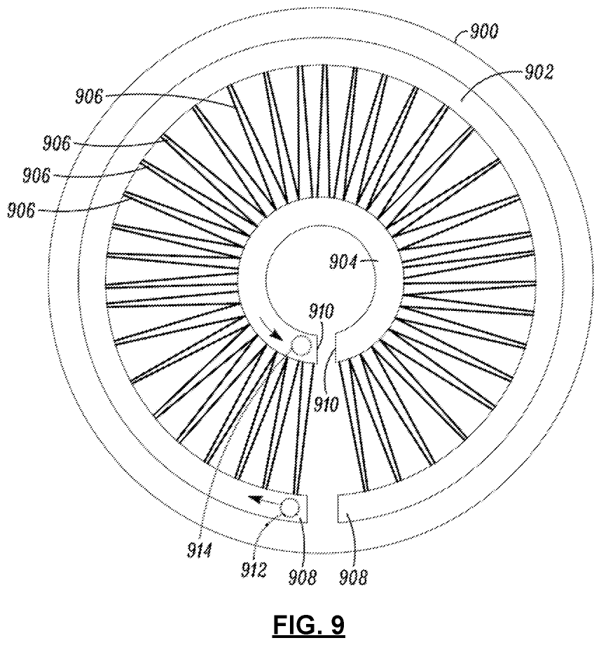

FIG. 9 shows a portion 900 of an example substrate support including non-continuous annular-shaped manifolds 902, 904 and varying width mesochannels, some of which designated 906, which extend radially between the manifolds 902, 904. In one embodiment, the manifold 902 is a supply manifold and the manifold 904 is a return manifold. As shown, the mesochannels gradually increase in width from the supply manifold 902 to the return manifold 904, are narrowest at the supply manifold 902 and are widest at the return manifold 904. In another embodiment, the mesochannels are widest at the supply manifold 902 and gradually narrow towards the return manifold 904, such that the mesochannels are narrowest at the return manifold 904.

In yet another embodiment, the manifold 902 is a return manifold, and the manifold 904 is the supply manifold. The mesochannels may also very in width for this embodiment as described above. The mesochannels may be widest at either of the manifolds 902, 904.

In another embodiment, the mesochannels have different variations in width, such that the overall width profiles of the mesochannels are different to provide different amounts of cooling in different areas of the substrate support. For example, some of the mesochannels may be widest near the manifold 902 and others may be widest near the manifold 904.

Any number of mesochannels may be included in the portion 900 and the spacing between the mesochannels may be set to provide a predetermined temperature profile. The manifolds 902, 904 may be discontinuous as shown. The manifold 902 includes ends 908 with a gap G1 between the ends 908. The manifold 904 includes ends 910 with a gap G2 between the ends 910. The manifold 902 may include an input opening 912 and the manifold 904 may include an output opening 914. The openings 912, 914 may be near ends of the manifolds 902, 904 or may be located at other positions along the manifolds 902, 904. Coolant may be supplied via a channel to the input opening 912 and return via the output opening 914. Inclusion of a single input opening and a single output opening assures that fluid flows inside the manifolds in a single direction. If the manifolds 902, 904 were continuous, then fluid may flow in different directions causing fluid mixing and possibly reverse flow. The supply manifold 902 may be located near an outer circumferential edge of the substrate support and the return manifold 904 may be located radially inward near a center of the substrate support as shown. In another embodiment, coolant flow is reversed, such that the manifold 904 performs as a supply manifold and the manifold 902 performs as a return manifold. As shown, the coolant flows into the supply manifold 902, radially inward through the mesochannels, and then out the return manifold 904.

The portion 900 has a 2-3 times higher overall heat transfer coefficient than a conventional cooling channel. In an embodiment, the cross-sections of the mesochannels of the portion 900 are the same and thus the heat transfer coefficients of the mesochannels are the same. Since the microchannels extend radially and in a linear manner, the lengths of the mesochannels are short. By including short mesochannels, the change in temperature of the coolant in the mesochannels is significantly reduced as compared to other arrangements having longer mesochannels. Increased cooling reduces substrate temperatures during processing.

Since the cross-sections of the mesochannels of the portion 900 increase in size from the supply manifold 902 to the return manifold 904, the fluid velocities and heat transfer coefficients of the mesochannels decrease from the supply manifold 902 to the return manifold 904 along the microchannels. The fluid velocities and heat transfer coefficients may decrease less, remain the same or increase by changing the widths of the mesochannels from that shown. Some alternative examples are stated above.

The mesochannels of the portion 900 as shown provide increased cooling near the center of the substrate support due to denser channel packaging. This is compensated for by widening the mesochannels near the return manifold 904 and/or the center of the substrate support, which reduces fluid velocity at the center as compared to near the outer circumferential edge of the substrate support.

The mesochannels disclosed herein may be manufactured to have 3-D profiles to vary channel distance from top surfaces of substrate supports to aid in, for example, increasing temperature uniformity laterally across the substrate supports. Examples of mesochannels having varying channel distances from top surfaces are shown in FIGS. 10-12.

FIG. 10 shows a portion 1000 of a substrate support illustrating a mesochannel 1002 disposed at varying vertical levels within the substrate support. The mesochannel 1002 is shown as an example. Any of the mesochannels disclosed above and described with respect to FIGS. 1-9 may be disposed at varying levels within a substrate support. As shown, the mesochannel 1002 has a uniform cross-sectional height H1 along a length of the mesochannel 1002 and is disposed on an angle relative to at least one of a horizontal plane 1005, a bottom surface 1004 of the portion 1000, and a top surface 1006 of the portion 1000. The horizontal plane 1005 may extend parallel to one or more of the surfaces 1004, 1006. The portion 1000 may include one or more layers and/or one or more plates of the substrate support. As shown, a vertical level H2 of the mesochannel 1002 varies radially and along a diameter of the substrate support. The vertical level H2 of the mesochannel 1002 also varies along a length of the mesochannel 1002. Although shown as decreasing in a single direction, the vertical level H2 may transition between increasing and decreasing multiple times along the length of the mesochannel 1002.

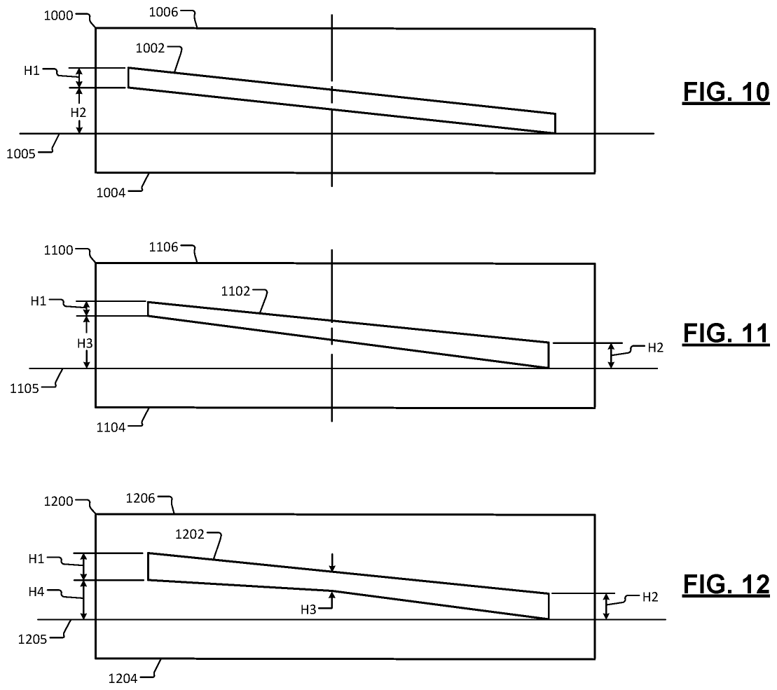

FIG. 11 shows a portion 1100 of a substrate support illustrating a mesochannel 1102 disposed at varying vertical levels within the substrate support and having cross-sections that vary in height. The mesochannel 1102 is shown as an example. Any of the mesochannels disclosed above and described with respect to FIGS. 1-9 may have varying cross-sectional heights and be disposed at varying levels within a substrate support. As shown, the mesochannel 1102 has cross-sections that vary in height and is disposed on an angle relative to at least one of a horizontal plane 1105, a bottom surface 1104 of the portion 1100, and a top surface 1106 of the portion 1100. As shown, the cross-section heights of the mesochannel 1102 vary radially and along a diameter of the substrate support from a shortest height H1 to a tallest height H2. The cross-section heights of the mesochannel 1102 vary along a length of the mesochannel 1102. Although shown as increasing in a single direction, the cross-section heights of the mesochannel 1102 may transition between increasing and decreasing multiple times along the length of the mesochannel 1102.

The horizontal plane 1105 may extend parallel to one or more of the surfaces 1104, 1106. The portion 1100 may include one or more layers and/or one or more plates of the substrate support. As shown, the vertical level H3 varies radially and along a diameter of the substrate support. The vertical level H3 of the mesochannel 1102 also varies along a length of the mesochannel 1102. Although shown as decreasing in a single direction, the vertical level H3 may transition between increasing and decreasing multiple times along the length of the mesochannel 1102.

FIG. 12 shows a portion 1200 of a substrate support illustrating a mesochannel 1202 including cross-section heights that transition between decreasing and increasing along a length of the mesochannel 1202. The mesochannel 1202 is shown as an example. Any of the mesochannels disclosed above and described with respect to FIGS. 1-9 may have varying cross-sectional heights and be disposed at varying levels within a substrate support. As shown, the mesochannel 1202 has varying cross-section heights and is disposed on an angle relative to at least one of a horizontal plane 1205, a bottom surface 1204 of the portion 1200, and a top surface 1206 of the portion 1200. As shown, the cross-section heights of the mesochannel 1202 vary radially and along a diameter of the substrate support from tallest heights H1, H2 at radially outermost edges of the mesochannel 1202 to a shortest height H3 at a center of the mesochannel 1202. Although shown as transitioning a single time from decreasing to increasing, the cross-section heights of the mesochannel 1202 may transition between increasing and decreasing one or more times along the length of the mesochannel 1202.

The horizontal plane 1205 may extend parallel to one or more of the surfaces 1204, 1206. The portion 1200 may include one or more layers and/or one or more plates of the substrate support. As shown, the vertical level H3 varies radially and along a diameter of the substrate support. The vertical level H4 of the mesochannel 1202 also varies along a length of the mesochannel 1202. Although shown as decreasing in a single direction, the vertical level H4 may transition between increasing and decreasing multiple times along the length of the mesochannel 1202.

The dimensions of the mesochannels disclosed herein including the cross-section heights and widths of the mesochannels may vary and be set to compensate for temperature non-uniformities. By varying the dimensions, the flow rates of coolant vary to provide increased or decreased cooling, which allows for the temperatures to be adjusted to provide a predetermined temperature profile.

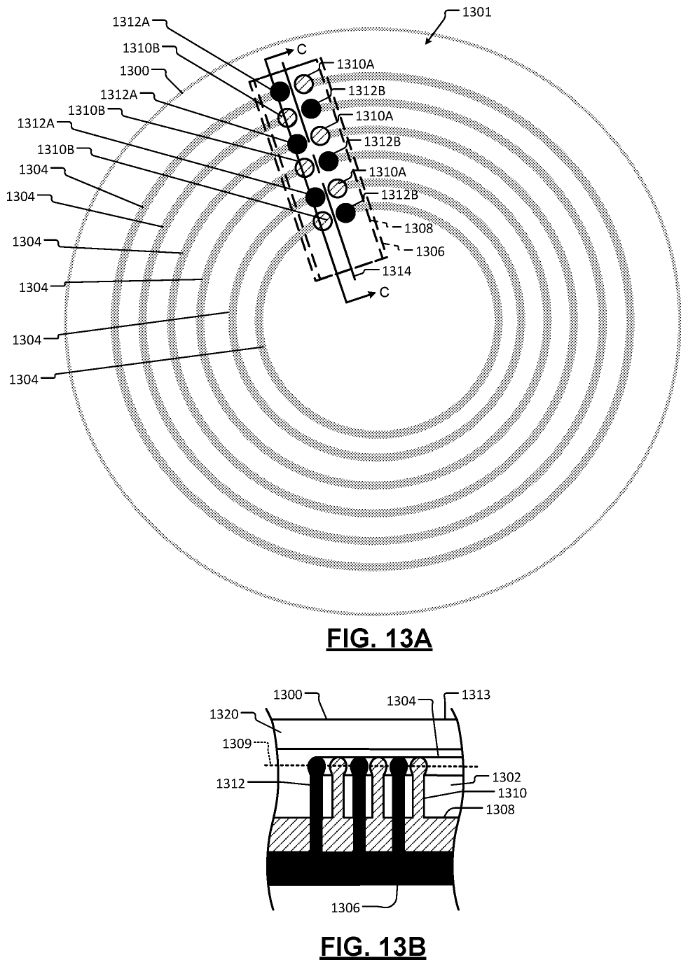

FIGS. 13A and 13B show a portion of a substrate support 1300 including a mesochannel assembly 1301 and a single layer 1302 of mesochannel channels 1304 with an alternating supply and return channel pattern where adjacent supply and return channels having opposite directions of coolant flow. The mesochannel assembly 1301 includes mesochannels 1304, an inlet (or supply) manifold 1306 and an outlet (or return) manifold 1308. The mesochannels 1304 may extend parallel to a same plane 1309 and are connected to supply channels 1310A, 1310B (collectively 1310) and the return channels 1312A, 1312B (collectively 1312). The plane 1309 may extend through the mesochannels 1304 and/or be parallel to a top surface 1313 of the substrate support 1300. The supply channels 1310 are connected to the supply manifold 1306. The return channels 1312 are connected to the return manifold 1308.

The return manifold 1308 may be stacked on the supply manifold 1306 as shown, or the supply manifold 1306 may be stacked on the return manifold 1308. The channels (e.g., the supply channels 1310) of the lower manifold may extend through the upper manifold (e.g., the return manifold 1308) and/or a layer thereof to corresponding ones of the mesochannels 1304. The supply channels 1310 and the return channels 1312 are connected to corresponding ones of the mesochannels 1304. The supply channels 1310 and the return channels 1312 are arranged in an alternating pattern along the manifolds 1306, 1308. The supply channels 1310 face the return channels 1312 relative to, for example, a centerline 1314 of the manifolds 1306, 1308.

The alternating connections of the supply channels 1310 and the return channels 1312 to the mesochannels 1304 results in adjacent mesochannels having opposite direction of coolant flow. In the example shown, the mesochannels connected to the supply channels 1310B and the return channels 1312B have coolant flow in a clockwise direction when viewed from a top of the substrate support 1300. The mesochannels connected to the supply channels 1310A and the return channels 1312A have coolant flow in a counterclockwise direction when viewed from a top of the substrate support 1300. This provides an averaging effect of cooling across the substrate support 1300 to provide an improved uniform temperature distribution and as a result a more uniform heat transfer coefficient distribution across the substrate support 1300. By alternating the coolant flow in the adjacent mesochannels in a same layer, a more compact design is provided, where the overall height of the mesochannel assembly may be reduced compared to the mesochannel assemblies in FIGS. 4A-6B. This arrangement also allows for shallower depth placement of mesochannels and thus closer placement of microchannels to an upper surface of a substrate support.

Although the layer 1302 is shown as being in contact with the layer 1308, an intermediate separation layer may be disposed between the layers 1302, 1308. Also, although the layer 1308 is shown as being in contact with the layer 1306, an intermediate separation layer may be disposed between the layers 1302, 1306. A top layer 1320 may be disposed on the layer 1302. The top layer 1320 may include electrostatic clamping electrodes or may be void of electrostatic clamping electrodes. The top layer 1320 may be an uppermost layer of the substrate support 1300.

At least some of the features of each of the embodiments of FIGS. 1-12 are applicable to the embodiments of FIG. 13. For example, the substrate support 1300 may include any number of mesochannel assemblies, the mesochannels 1304 may have the same or different cross-sectional dimensions.

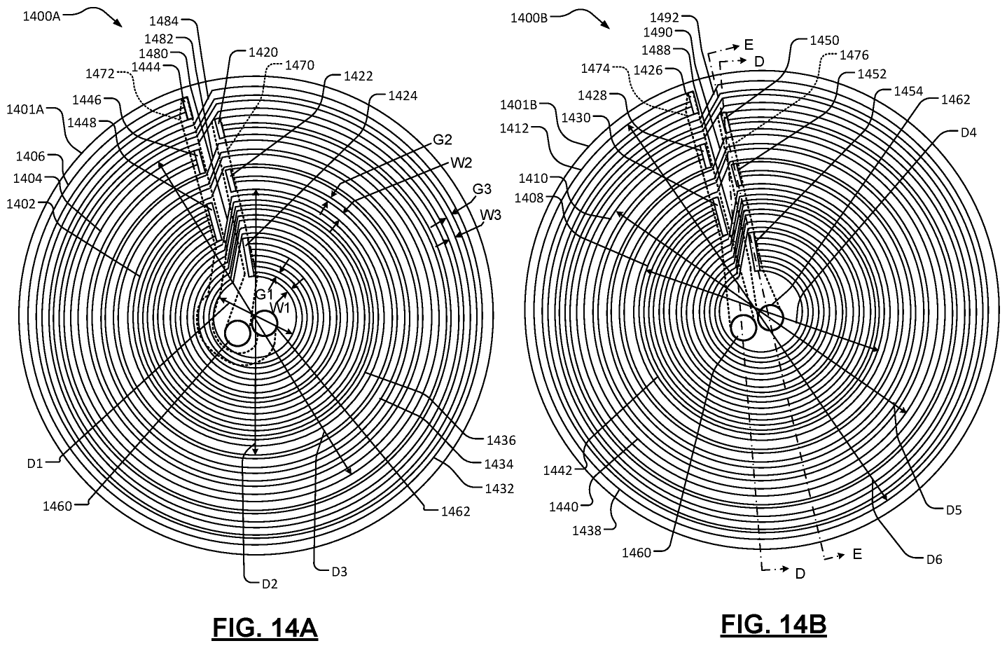

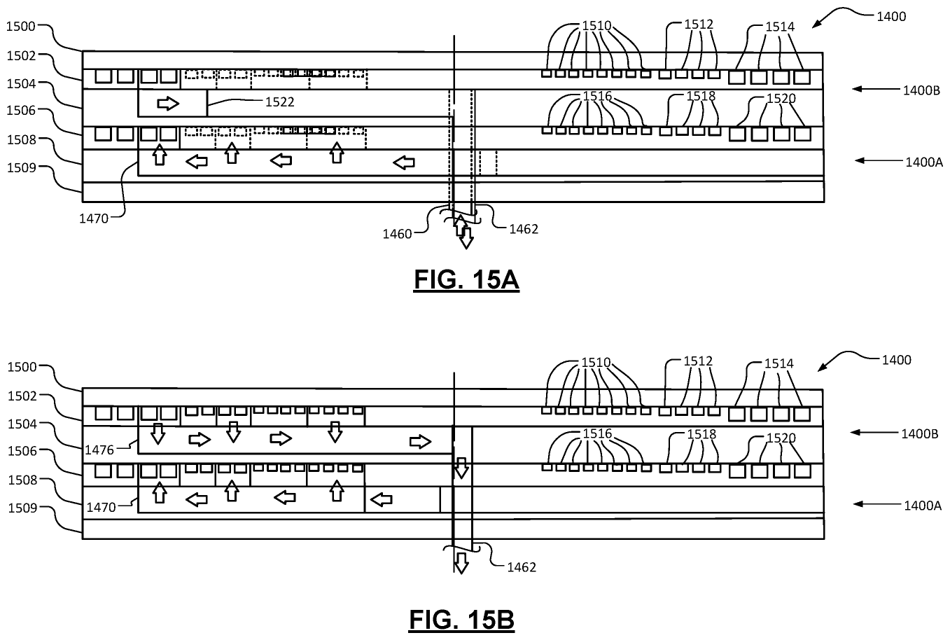

A substrate support having a single spiral channel extending laterally across the substrate support, for example, from at least a point near a center of the substrate support to a point near a radially outward peripheral edge of the substrate support, can be long and result in a high pressure drop. The high-pressure drop is due to the long length of the single spiral channel. To mitigate this, the spiral channel may be divided into multiple channels having respective inputs and outputs. As an example, the spiral channel may be divided into three spiral channels of different sizes, where a second spiral channel is arranged radially inward of a first spiral channel, and where a third spiral channel is arranged radially inward of the second spiral channel. This helps split flow of fluid to be through multiple spiral channels and reduces the running length of each spiral channel, which reduces pressure drop. The pressure drops of the three spiral channels being less than the pressure drop of the single spiral channel. The multiple spiral channels may be mesochannels, minichannels and/or microchannels. Examples of which are shown in FIGS. 14A-15B.

FIGS. 14A and 14B show a lower portion 1400A and an upper portion 1400B of an example substrate support, which are collectively referred to as portion 1400. The lower portion 1400A includes lower layers 1401A having a first set of spiral-shaped mesochannel assemblies and the upper portion 1400B includes upper layers 1401B having a second set of spiral-shaped mesochannel assemblies. The spiral-shaped mesochannel assemblies of the portions 1400A, 1400B may replace the mesochannel assembly 110 of FIG. 1 and be connected to the valve assembly 117 and/or pump 113 of FIG. 1.

In the example shown, the first set of spiral-shaped mesochannel assemblies include three mesochannel assemblies 1402, 1404, 1406, although any number of mesochannel assemblies may be included. Similarly, the second set of spiral-shaped mesochannel assemblies includes three mesochannel assemblies 1408, 1410, 1412 but any number of mesochannel assemblies may be included. Each of the mesochannel assemblies 1402, 1404, 1406, 1408, 1410, 1412 includes a supply manifold, mesochannels and a return manifold. The supply manifolds 1420, 1422, 1424, 1426, 1428, 1430, mesochannels (one in each mesochannel assembly is respectively designated 1432, 1434, 1436, 1438, 1440, 1442), and return manifolds 1444, 1446, 1448, 1450, 1452, 1454 are shown. The upper layers 1401B may be disposed above and stacked on the lower layers 1401A. Coolant may flow through the mesochannel assemblies 1402, 1404, 1406 in a same direction (e.g., clockwise direction). Coolant may flow through the mesochannel assemblies 1408, 1410, 1412 in a same direction (e.g., counterclockwise direction). Coolant flow through the mesochannel assemblies 1402, 1404, 1406 may be in a different direction than coolant flow through the mesochannel assemblies 1408, 1410, 1412.

The portion 1400 includes a single POC provided by the single pair of channels 1460, 1462 that supply coolant to and receive the coolant from the mesochannel assemblies 1402, 1404, 1406, 1408, 1410, 1412 via cutouts 1470, 1472, 1474, 1476. The channel 1460 supplies coolant to the first cutout 1470, which supplies coolant to the manifolds 1420, 1422, 1424. The channel 1462 receives coolant from the second cutout 1472, which receives coolant from the manifolds 1444, 1446, 1448. The channel 1460 also supplies coolant to the third cutout 1474, which supplies coolant to the manifolds 1426, 1428, 1430. The channel 1462 also receives coolant from the fourth cutout 1476, which receives coolant from the manifolds 1450, 1452, 1454.

The mesochannel assemblies 1402, 1404, 1406, 1408, 1410, 1412 may have various patterns, dimensions, and gaps therebetween. Some example innermost and outer most diameters of the mesochannel assemblies are shown and designated D1-D6. The mesochannels of different mesochannel assemblies may have different dimensions, such as different heights and widths. Each of the mesochannels may have any number of loops. The mesochannel assemblies may have any number of mesochannels.

The mesochannels of the mesochannel assemblies may be concentric and include transition channels connecting inner mesochannels to outer mesochannels. Sets of transition channels are shown for the mesochannel assemblies 1402, 1404, 1406, where one from each set is designated 1480, 1482, 1484. Sets of transition channels are shown for the mesochannel assemblies 1408, 1410, 1412, where one from each set is designated 1488, 1490, 1492. The transition channels may extend diagonally as shown, have an ‘S’-shaped pattern, or other pattern to connect different mesochannels of the same mesochannel assembly. The mesochannel assemblies may have independently varying: dimensions including heights and widths; gaps between mesochannels; gaps between mesochannel assemblies; number of mesochannels; and number of loops in each mesochannel assembly; and/or number of loops in a layer of the corresponding substrate support.

Example gaps G1, G2, G3 and mesochannel widths W1, W2, W3 are shown. The gaps G1, G2, G3 are gaps between mesochannels respectively of the mesochannel assemblies 1402, 1404, 1406. The widths W1, W2, W3 are widths of the mesochannels of the mesochannel assemblies 1402, 1404, 1406. The gaps G1, G2, G3 may be the same or different. The widths W1, W2, W3 may be the same or different.

The mesochannel assemblies 1408, 1410, 1412 may have a same pattern as the mseochannel assemblies 1402, 1404, 1406 including the same layout, dimensions, gaps, widths, heights, etc. However, the direction of coolant flow may be the opposite, such that the supply manifolds 1426, 1428, 1430 of the mesochannel assemblies 1408, 1410, 1412 are above the return manifolds 1444, 1446, 1448 of the mesochannel assemblies 1402, 1404, 1406. Similarly, the return manifolds 1450, 1452, 1454 of the mesochannel assemblies 1408, 1410, 1412 are above the supply manifolds 1420, 1422, 1424 of the mesochannel assemblies 1402, 1404, 1406.

FIG. 15A is a cross-section through section line D-D of FIG. 14B for the stacked combination of the portions 1400A, 1400B of FIGS. 14A and 14B. FIG. 15B is a cross-section through section line E-E of FIG. 14B for the stacked combination of the portions 1400A, 1400B of FIGS. 14A and 14B. The portion 1400B includes an upper layer 1500, a mesochannel layer 1502, and a cutout layer 1504. The portion 1400A includes an a mesochannel layer 1506, a cutout layer 1508 and a lower layer 1509.

The mesochannel layer 1502 includes mesochannels 1510, 1512, 1514 of the mesochannel assemblies 1408, 1410, 1412 of FIG. 14B. The mesochannel layer 1506 includes mesochannels 1516, 1518, 1520 of the mesochannel assemblies 1402, 1404, 1406 of FIG. 14A. The cutout layer 1504 includes the cutouts 1474, 1476 of FIG. 14B. A portion 1522 of the cutout 1476 is shown in FIG. 15A. The cutout 1476 is shown in FIG. 15B. The cutout layer 1508 includes the cutouts 1470, 1472 of FIG. 14A. The cutout 1470 is shown in FIG. 15A. The cutout 1470 is shown in FIG. 15B.

The above-described example mesochannel assemblies of FIGS. 14A-15B provide a greater than 30% higher overall heat transfer coefficient as compared to a conventional single channel with 30% lesser pressure drop as compared to a conventional single channel. The reduced pressure drops of the mesochannel assemblies increases total flow rate which in turn reduces fluid average and exit temperatures, which increases heat carrying capacity. In an existing conventional channel, the fluid flow rate cannot be increased from 17 litres per minute (lpm) to 25 lpm because with the increase in flow, pressure drop also increases from 14 pounds per square inch gauge (psig) to 30 psig, which can be out of available pump capacity. With the arrangement of FIGS. 14A-15B, the flow rate may be increased to 25 lpm within a reduced amount of pressure drop of, for example, 12 psig. This helps to achieve reduced substrate support temperatures than conventional substrate supports experiencing the same heat load. The examples allow for high temperature uniformity laterally across a substrate support. The higher temperature uniformity provides increased yield. The examples provide increased cooling for reduced processing temperatures.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support comprising:
a body configured to support a substrate within a substrate processing system; and
a first mesochannel assembly disposed in the body and comprising
a first plurality of mesochannels, wherein the first plurality of mesochannels extend parallel to each other and in a spiral pattern,
a first supply manifold supplying coolant to each of the first plurality of mesochannels, and
a first return manifold receiving the coolant from the first plurality of mesochannels,
wherein
the first plurality of mesochannels is disposed between the first supply manifold and the first return manifold to facilitate flow of the coolant from the first supply manifold to the first return manifold, and
the first plurality of mesochannels are connected in parallel such that first ends of the first plurality of mesochannels are connected to the first supply manifold and second ends of the first plurality of mesochannels are connected to the first return manifold.

2. The substrate support of claim 1, wherein a cross-section of each of the first plurality of mesochannels has a hydraulic diameter of less than 3.0 mm.

3. The substrate support of claim 1, wherein the first supply manifold is disposed radially inward of the first return manifold.

4. The substrate support of claim 1, wherein the first supply manifold is disposed radially outward of the first return manifold.

5. (canceled)

6. The substrate support of claim 1, wherein the first plurality of mesochannels extend from a center area of the body to an area adjacent an outer circumferential edge of the body and back to the center area of the body.

7. The substrate support of claim 1, wherein the first supply manifold is disposed adjacent to the first return manifold.

8. The substrate support of claim 7, wherein the first supply manifold and the first return manifold are disposed in a center area of the body.

9. The substrate support of claim 7, wherein the first supply manifold and the first return manifold are disposed along an outer circumferential edge of the body.

10. The substrate support of claim 7, wherein the first supply manifold and the first return manifold extend in a radial direction.

11-13. (canceled)

14. The substrate support of claim 1, wherein at least one of cross-section widths and cross-section heights of the first plurality of mesochannels are uniform.

15. The substrate support of claim 1, wherein:
the first plurality of mesochannels comprise
a first mesochannel having a first cross-section width, and
a second mesochannel having a second cross-section width; and
the second cross-section width is smaller than the first cross-section width.

16. The substrate support of claim 1, wherein the first plurality of mesochannels have a same length.

17. The substrate support of claim 1, wherein:
the first plurality of mesochannels comprise
a first mesochannel having a first length, and
a second mesochannel having a second length; and
the second length is different than the first length.

18-20. (canceled)

21. The substrate support of claim 1, wherein the body comprises:
a first plate defining a first portion of the first mesochannel assembly; and
a second plate attached to the first plate and defining a second portion of the first mesochannel assembly.

22. The substrate support of claim 21, wherein:
the first portion includes a plurality of grooves;
the plurality of grooves define three sides of each of the first plurality of mesochannels; and
the second portion including a fourth side of each of the first plurality of mesochannels.

23. The substrate support of claim 1, wherein the body comprises:
a first layer comprising the first mesochannel assembly, and
a second layer comprising a second mesochannel assembly.

24. The substrate support of claim 23, wherein:
the second mesochannel assembly comprises
a second plurality of mesochannels,
a second supply manifold supplying coolant to each of the second plurality of mesochannels, and
a second return manifold receiving the coolant from the second plurality of mesochannels; and
the second plurality of mesochannels is disposed between the second supply manifold and the second return manifold to facilitate flow of the coolant from the second supply manifold to the second return manifold.

25. The substrate support of claim 24, further comprising:
a first crossover channel extending between the first supply manifold of the first mesochannel assembly to the second supply manifold of the second mesochannel assembly; and
a second crossover channel extending between the first return manifold of the first mesochannel assembly to the second return manifold of the second mesochannel assembly.

26. The substrate support of claim 24, wherein the first mesochannel assembly is disposed over the second mesochannel assembly.

27. The substrate support of claim 24, wherein:
the first layer is disposed over the second layer;
the first supply manifold of the first mesochannel assembly is disposed over the second return manifold of the second mesochannel assembly; and
the first return manifold of the first mesochannel assembly is disposed over the second supply manifold of the second mesochannel assembly.

28. The substrate support of claim 1, wherein the body comprises a plurality of mesochannel assemblies including the first mesochannel assembly.

29. The substrate support of claim 28, wherein the plurality of mesochannel assemblies are each disposed in at least a portion of a same layer of the body.

30. The substrate support of claim 28, wherein the plurality of mesochannel assemblies are each disposed in and defined by a same two plates of the body.

31. The substrate support of claim 28, wherein the plurality of mesochannel assemblies are each disposed in different layers of the body.

32-37. (canceled)

38. The substrate support of claim 1, wherein the first plurality of mesochannels comprise at least one mesochannel disposed at varying vertical levels within the body.

39. The substrate support of claim 1, wherein the first plurality of mesochannels comprise at least one mesochannel having cross-sections that vary in height along a length of the at least one mesochannel.

40. The substrate support of claim 1, wherein the first plurality of mesochannels comprise at least one mesochannel having cross-sections that transition between increasing in height and decreasing in height.

41. The substrate support of claim 1, wherein:
the first mesochannel assembly comprises a second plurality of mesochannels;
the coolant flows through the first plurality of mesochannels in a first direction; and
the coolant flows through the second plurality of mesochannels in a second direction opposite the first direction.

42. The substrate support of claim 41, wherein:
the coolant flows through the first plurality of mesochannels in a clockwise direction; and
the coolant flows through the second plurality of mesochannels in a counterclockwise direction.

43. The substrate support of claim 41, wherein the first plurality of mesochannels are alternatingly arranged with the second plurality of mesochannels, such that each of the first plurality of mesochannels is adjacent one or two of the second plurality of mesochannels.

44. The substrate support of claim 43, wherein:
a plane extends through each of the first plurality of mesochannels and each of the second plurality of mesochannels; and
the plane is parallel to a top surface of the substrate support.

45. The substrate support of claim 41, wherein the first supply manifold is disposed on the first return manifold.

46. The substrate support of claim 41, wherein the first return manifold is disposed on the first supply manifold.

47. The substrate support of claim 41, wherein an intermediate layer is disposed between the first supply manifold and the first return manifold.

48. The substrate support of claim 1, wherein:
the body comprises a first channel layer comprising a first plurality of mesochannel assemblies; and
the first plurality of mesochannel assemblies comprise the first mesochannel assembly and a second mesochannel assembly arranged radially inward of the first mesochannel assembly.

49. The substrate support of claim 48, wherein the second mesochannel assembly comprises a second supply manifold, a second return manifold and a second plurality of mesochannels connecting the second supply manifold to the second return manifold.

50. The substrate support of claim 48, wherein the first plurality of mesochannel assemblies comprise a third mesochannel assembly arranged radially inward of the second mesochannel assembly.

51. The substrate support of claim 48, wherein coolant flow through the first mesochannel assembly is in a same direction as coolant flow through the second mesochannel assembly.

52. The substrate support of claim 48, wherein the body comprises a first cutout layer comprising a first cutout supplying coolant to a first plurality of manifolds of the first plurality of mesochannel assemblies.

53. The substrate support of claim 52, wherein the first cutout layer comprises a second cutout receiving coolant from a second plurality of manifolds of the first plurality of mesochannel assemblies.

54. The substrate support of claim 48, wherein the body comprises a second channel layer disposed on the first channel layer and comprising a second plurality of mesochannel assemblies.

55. The substrate support of claim 54, wherein a pattern of the second plurality of mesochannel assemblies is a same pattern as the first plurality of mesochannel assemblies; and coolant flows through the second plurality of mesochannel assemblies in an opposite direction as coolant flow through the first plurality of mesochannel assemblies.

56. The substrate support of claim 54, wherein the body comprises:
a first cutout layer comprising a first cutout supplying coolant to or receiving coolant from a first plurality of manifolds of the first plurality of mesochannel assemblies; and
a second cutout layer comprising a second cutout supplying coolant to or receiving coolant from a second plurality of manifolds of the second plurality of mesochannel assemblies.

57. The substrate support of claim 48, wherein the first mesochannel assembly comprises transition channels connecting inner mesochannels to outer mesochannels, each of the transition channels connecting a respective one of the inner mesochannels to a respective one of the outer mesochannels, each of the outer mesochannels being disposed radially outward of at least one of the inner mesochannels.

58. The substrate support of claim 48, further comprising:
a supply channel supplying coolant to the first plurality of mesochannel assemblies; and
a return channel receiving coolant from the first plurality of mesochannel assemblies.

59. A substrate processing system comprising:
the substrate support of claim 1;
a first line supplying the coolant to the first supply manifold;
a second line supplying the coolant to the first return manifold; and
a pump connected to at least one of the first line and the second line and circulating the coolant through the first mesochannel assembly.

60. The substrate processing system of claim 59, further comprising:
a temperature sensor configured to detect a temperature within a processing chamber,
wherein the substrate support is disposed in the processing chamber; and
a controller configured to control operation of the pump based on the temperature.
